(19) United States
(12) Patent Application Publication
(10) Pub. No.: US 2005/0278043 A1
(43) Pub. Date: Dec. 15, 2005

(54) Method and device for solving sound distortion problem of sound playback and recording device

(75) Inventor: Chin-Fu Hung, Hsin Chu (TW)

Correspondence Address: TROXELL LAW OFFICE PLLC, SUITE 1404, 5205 LEESBURG PIKE, FALLS CHURCH, VA, 22041, US

(73) Assignee: Premier Image Technology Corporation

(21) Appl. No.: 10/863,224

(22) Filed: Jun. 9, 2004

(51) Int. Cl. G06F 17/00; H03G 3/00

(52) U.S. Cl. 700/94; 381/61; 381/106; 381/104

(57) ABSTRACT

A method and a device for solving the sound distortion problem of a sound playback and recording device are used to avoid the data overflow phenomenon when the sound playback and recording device performs conversion between analog and digital formats. At least a gamma table is used to adjust the amplifications to avoid the signal overdrive phenomenon when the sound playback and recording device records sound. Similarly, when converting a digital sound signal back to an analog sound signal, a gamma table is referred to for adjusting the amplifications. The signal overdrive phenomenon can thus be effectively solved to reduce the probability of sound distortion of the sound playback and recording device when a digital sound signal is restored into an analog sound signal.

### FIELD OF THE INVENTION

The present invention relates to a method and a device for solving the sound distortion problem of a sound playback and recording device and, more particularly, to a method making use of gamma tables to avoid the signal overdrive phenomenon during conversion between digital and analog formats, thereby solving the sound distortion problem generated when a sound playback and recording device plays an analog signal.

### BACKGROUND OF THE INVENTION

Sound processing can generally be divided into analog and digital methods. Along with progress of the information and computer technology, the combination of analog and digital methods has become inevitable in sound playback devices.

Integrating advantages of the analog and digital methods not only can provide situated sound feel, but also can facilitate self music editing for users. Conventional products have thus been gradually replaced with integrated sound playback devices of this kind.

During conversion between an analog signal and a digital signal, however, if the amount of input data is too large, the data overflow phenomenon may happen. For a sound playback device, if the input sound signal is stronger, the converted digital sound signal will have a large probability of signal overdrive.

Similarly, if the digital sound signal with overflow is to be converted into analog format for output, an analog sound signal with overflow will be generated, hence causing the sound distortion phenomenon. In other words, a front-stage distorted signal will naturally produce a back-stage distorted output signal.

In the prior art, there has been a method for solving the signal overdrive problem, wherein an auto-level control component is installed at the front stage of the sound playback device to avoid the signal overdrive phenomenon during conversion of a sound signal between analog and digital formats. However, an extra auto-level control component is required in this method, hence increasing the cost of the sound playback device.

Accordingly, the present invention aims to propose a method and a device for solving the sound distortion problem of a sound playback and recording device, which make use of at least a gamma table to adjust amplifications to solve the sound distortion problem due to data overflow.

### SUMMARY OF THE INVENTION

An object of the present invention is to propose a method and a device for solving the sound distortion problem of a sound playback and recording device to overcome the data overflow problem during conversion between digital and analog formats of the sound playback and recording device. In this method, an analog sound signal is first input. Next, the analog sound signal is converted into a digital sound signal. At least a gamma table is then used to amplify smaller volumes with larger amplifications and amplify larger volumes with smaller amplifications. Subsequently, the digital sound signal amplified with the gamma table is stored. Similarly, a gamma table is also used for amplification for output to restore the digital sound signal to the analog sound signal without the signal overdrive phenomenon. The probability of sound distortion of the sound playback and recording device can thus be reduced.

The various objects and advantages of the present invention will be more readily understood from the following detailed description when read in conjunction with the appended drawings, in which:

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a simplified circuit block diagram of a conventional sound playback and recording device;

FIG. 2 is a detailed circuit block diagram of a conventional sound playback and recording device;

FIG. 3 is a complete flowchart for sound playback and recording of the present invention;

FIG. 4 is an amplification diagram of a conventional gamma table;

FIG. 5 is a flowchart of a sound playback and recording device for sound recording of the present invention; and

FIG. 6 is a flowchart of a sound playback and recording device for sound playback of the present invention.

### DETAILED DESCRIPTION OF THE PREFERRED EMBODIMENTS

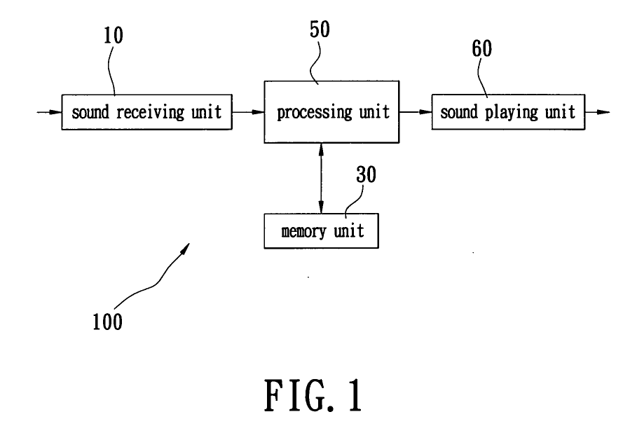

The present invention provides a method and a device for solving the sound distortion problem of a sound playback and recording device, which make use of at least a gamma table to solve the signal overdrive problem during conversion between digital and analog formats of a sound playback and recording device to avoid the sound distortion phenomenon generated when the sound playback and recording device plays an analog signal. As shown in FIG. 1, a sound playback and recording device 100 comprises a sound receiving unit 10 for receiving an analog sound signal. The analog sound signal is then sent to a processing unit 50 for further processing.

The processing unit 50 is used to perform various kinds of processing such as conversion, amplification and compression to the analog sound signal in turn. First, the analog sound signal is converted into a digital sound signal. Next, the digital sound signal is sent to a memory unit 30 for storage. When a user wants to play the sound signal, the processing unit 50 will fetch the digital sound signal from the memory unit 30 and perform inverse actions such as decompression, amplification, and conversion to restore the digital sound signal back to the analog sound signal. Finally, the analog sound signal is output to a sound playing unit 60 for playback of the analog sound signal.

In FIG. 1, the processing unit 50 can further edit the digital sound signal or generate various sound effects (e.g., equalization, reverberation and so on). Therefore, the processing unit 50 can be a digital signal processor (DSP). The fun of editing can thus be provided for the users.

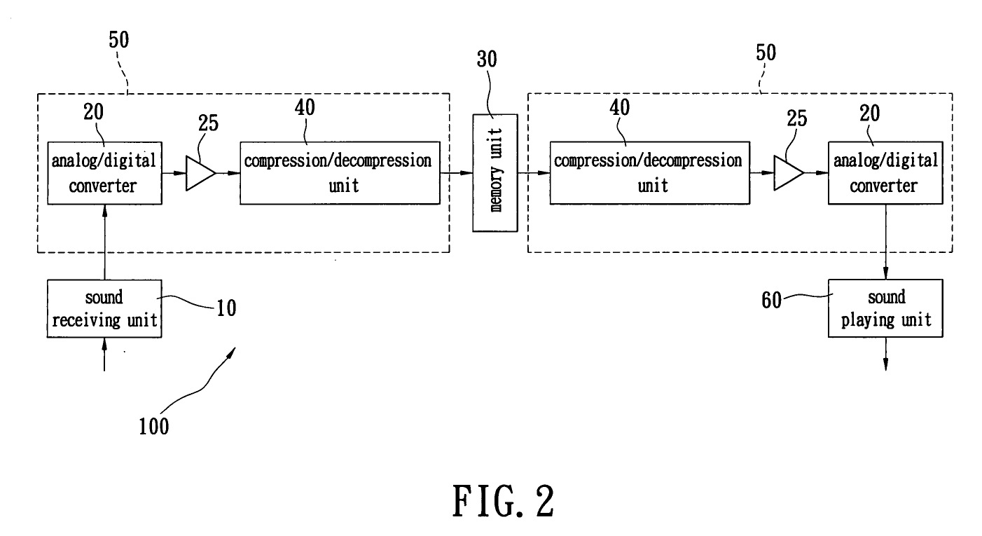

As shown in FIG. 2, after the sound receiving unit 10 receives an analog sound signal, the analog sound signal is first sent into an analog/digital converter 20 in the processing unit 50 for converting the analog sound signal into a digital sound signal. In order to avoid the signal overdrive phenomenon after conversion due to an excessively large input, it is necessary to sent to a gamma amplifier 50 connected to the analog/digital converter 20 for adjusting the amplifications.

The gamma amplifier 25 adjusts the volumes of the digital sound signal according to specific amplifications. If the input volume is smaller, the amplification is increased. Contrarily, if the input volume is larger, the amplification is decreased. The sound distortion phenomenon due to data overflow can thus be avoided when the sound playing unit 60 plays sound.

The amplifications can be adjusted according to a gamma table. That is, after a designer builds a gamma table, it is immediately set in the gamma amplifier 25 so that the volumes of a subsequently input digital sound signal can be adjusted according to the gamma table to avoid signal overdrive after conversion between analog and sound formats.

After amplified by the gamma amplifier 25, the digital sound signal is output to a compression/decompression unit 40 for compressing the digital sound signal to increase the storage capacity of the memory unit 30. When the digital sound signal is output from the memory unit 30, the compression/decompression unit 40 is required for decompression to restore the digital sound signal.

Similarly, when a user wants to play a digital sound signal in the memory unit 30, the processing unit 50 first fetches the digital sound signal from the memory unit 30. The compression/decompression unit 40 then decompresses the digital sound signal. Next, a gamma amplifier 25 amplifies the digital sound signal according to specific amplifications. An analog/digital converter 20 then restores the digital sound signal into the analog sound signal. Finally, the analog sound signal is output to a sound playing unit 60 for playing sound.

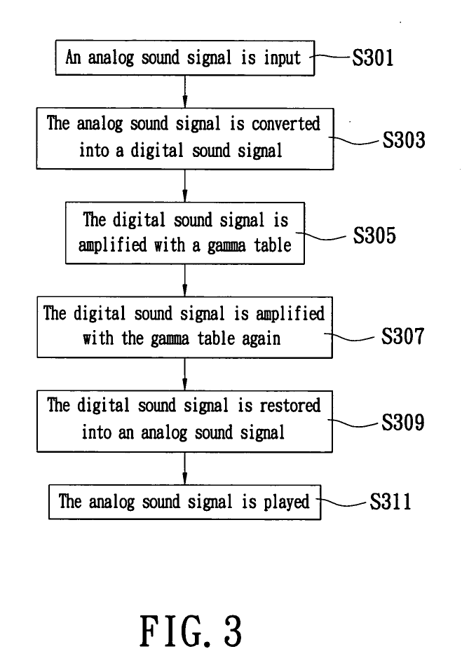

Reference is made to FIG. 3 as well as FIG. 2. First, an analog sound signal is input (S301). The analog sound signal is then converted into a digital sound signal by an analog/digital converter 20 (S303). Next, the digital sound signal is amplified with a gamma table (S305) to adjust the input volumes for avoiding the signal overdrive phenomenon.

In this embodiment, it is not necessary to store the digital sound signal in a memory unit 30. The digital sound signal can be directly output. The digital sound signal is amplified with the gamma table again (S307) to avoid too small volumes of the output. Next, the digital sound signal is restored to an analog sound signal by an analog/digital converter 20 (S309). Finally, the analog sound signal is played by a sound playing unit 60 (S311). The data overflow phenomenon of the sound playback and recording device 100 during conversion between analog/digital formats can be avoided. Moreover, the sound distortion problem generated when the sound playback and recording device plays sound can be avoided.

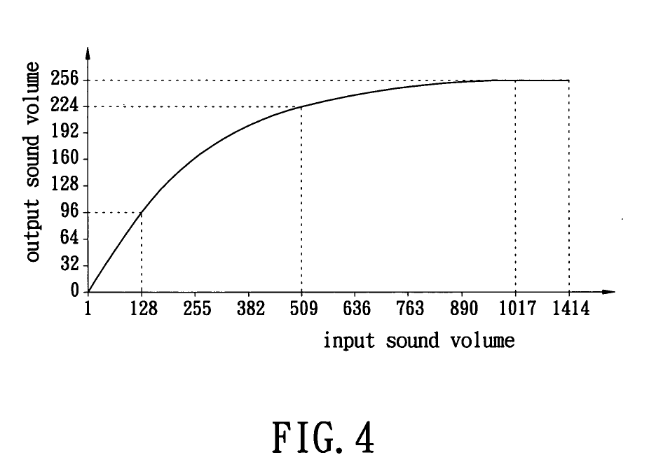

As shown in FIG. 4, the gamma table makes use of a nonlinear transformation to transform smaller input volumes into larger output volumes and larger input volumes into smaller output volumes. It can be clearly seen that the amplification at the input level 128 is larger than the amplification at the input level 509.

If the input volume exceeds a certain value, the output volume is kept at level 256 to avoid the sound distortion phenomenon when the sound playback and recording device 100 plays sound. In this embodiment, the gamma table is a nonlinear graph. In practical application, it can also be designed to be a linear transformation.

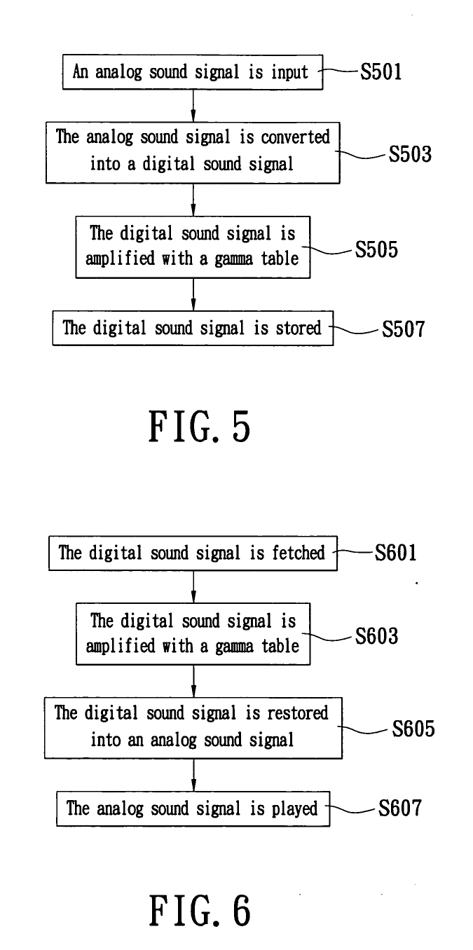

As shown in FIG. 5, an analog sound signal is first input (S501). The analog sound signal is then converted into a digital sound signal (S503). Next, the digital sound signal is amplified with a gamma table (S505) to amplify smaller volumes with larger amplifications and amplify larger volumes with smaller amplifications. Finally, the digital sound signal amplified with the gamma table is stored (S507) to reduce the probability of data overflow.

As shown in FIG. 6, the digital sound signal is fetched from the memory unit 30 (S601). The digital sound signal is then amplified with a gamma table (S603) to amplify smaller volumes with larger amplifications and amplify larger volumes with smaller amplifications. Next, the digital sound signal is restored to an analog sound signal (S605). Finally, the analog sound signal is sent to a sound playing unit 60 for playing the analog sound signal.

To sum up, the present invention provides a method and a device for solving the sound distortion problem of a sound playback and recording device to effectively solve the data overflow problem during conversion between digital and analog formats of the sound playback and recording device and also decrease the probability of sound distortion when the sound playback and recording device 100 plays sound.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

1. A method for solving the sound distortion problem of a sound playback and recording device, comprising the steps of:
a) inputting an analog sound signal;
b) converting said analog sound signal into a digital sound signal;
c) using at least a gamma table to amplify smaller volumes with larger amplifications and amplify larger volumes with smaller amplifications;
d) restoring said digital sound signal to an analog sound signal; and
e) playing said analog sound signal.

2. The method for solving the sound distortion problem of a sound playback and recording device as claimed in claim 1, further comprising a step of compressing or decompressing said digital sound signal after said Step c).

3. A method for solving the sound distortion problem of a sound playback and recording device, comprising the steps of:
a) inputting an analog sound signal;
b) converting said analog sound signal into a digital sound signal;
c) using at least a gamma table to amplify smaller volumes with larger amplifications and amplify larger volumes with smaller amplifications; and
d) storing said digital sound signal amplified with said gamma table.

4. The method for solving the sound distortion problem of a sound playback and recording device as claimed in claim 3, further comprising a step of compressing or decompressing said digital sound signal after said Step c).

5. A method for solving the sound distortion problem of a sound playback and recording device, comprising the steps of:
a) fetching a digital sound signal;
c) using at least a gamma table to amplify smaller volumes with larger amplifications and amplify larger volumes with smaller amplifications;
d) converting said digital sound signal into an analog sound signal; and
e) playing said analog sound signal.

6. The method for solving the sound distortion problem of a sound playback and recording device as claimed in claim 5, further comprising a step of compressing or decompressing said digital sound signal after said Step a).

7. A device for solving the sound distortion problem of a sound playback and recording device, the device comprising:
a sound receiving unit for input of an analog sound signal;
a processing unit for performing operations including compression, amplification, conversion and editing;
a memory unit for storing a digital sound signal; and
a sound playing unit for playing said analog sound signal.

8. The device for solving the sound distortion problem of a sound playback and recording device as claimed in claim 7, wherein said processing unit further comprises:
at least a compression/decompression unit for compressing/decompressing said digital sound signal;
at least a gamma amplifier for referring to at least a gamma table to amplify said digital sound signal; and
at least an analog/digital converter for performing conversion between analog and digital sound signals.

9. The device for solving the sound distortion problem of a sound playback and recording device as claimed in claim 7, wherein said processing unit is used to further edit said digital sound signal or generate various sound effects.

10. The device for solving the sound distortion problem of a sound playback and recording device as claimed in claim 9, wherein said processing unit is a digital signal processor.
